(19) United States
(12) Patent Application Publication
(10) Pub. No.: US 2021/0057182 A1
(43) Pub. Date: Feb. 25, 2021

(54) METHOD OF ENHANCING THE ENERGY AND BEAM CURRENT ON RF BASED IMPLANTER

(71) Applicant: Axcelis Technologies, Inc., Beverly, MA (US)

(72) Inventor: Shu Satoh, Byfield, MA (US)

(21) Appl. No.: 16/544,000

(22) Filed: Aug. 19, 2019

(51) Int. Cl. H01J 37/08; H01J 37/05; H01J 37/317

(52) U.S. Cl. CPC H01J 37/08; H01J 37/05; H01J 2237/057; H01J 2237/04735; H01J 2237/05; H01J 37/3171

(57) ABSTRACT

Methods and a system of an ion implantation system are configured for increasing beam current above a maximum kinetic energy of a first charge state from an ion source without changing the charge state at the ion source. Ions having a first charge state are provided from an ion source and are selected into a first RF accelerator and accelerated in to a first energy. The ions are stripped to convert them to ions having various charge states. A charge selector receives the ions of various charge states and selects a final charge state at the first energy. A second RF accelerator accelerates the ions to final energy spectrum. A final energy filter filters the ions to provide the ions at a final charge state at a final energy to a workpiece.

### TECHNICAL FIELD

The present disclosure relates generally to ion implantation systems, and more particularly to a system and method for increasing beam current available at a maximum energy for a charge state without using a higher charge state at an ion source.

### BACKGROUND

In the manufacture of semiconductor devices, ion implantation is used to dope semiconductors with impurities. Ion implantation systems are often utilized to dope a workpiece, such as a semiconductor wafer, with ions from an ion beam, in order to either produce n- or p-type material doping, or to form passivation layers during fabrication of an integrated circuit. Such beam treatment is often used to selectively implant the wafers with impurities of a specified dopant material, at a predetermined energy level, and in controlled concentration, to produce a semiconductor material during fabrication of an integrated circuit. When used for doping semiconductor wafers, the ion implantation system injects a selected ion species into the workpiece to produce the desired extrinsic material. Implanting ions generated from source materials such as antimony, arsenic, or phosphorus, for example, results in an “n-type” extrinsic material wafer, whereas a “p-type” extrinsic material wafer often results from ions generated with source materials such as boron, gallium, or indium.

A typical ion implanter includes an ion source, an ion extraction device, a mass analysis device, a beam transport device and a wafer processing device. The ion source generates ions of desired atomic or molecular dopant species. These ions are extracted from the source by an extraction system, typically a set of electrodes, which energize and direct the flow of ions from the source, forming an ion beam. Desired ions are separated from the ion beam in a mass analysis device, typically a magnetic dipole performing mass dispersion or separation of the extracted ion beam, whereby the ions are accelerated or decelerated to a final desired energy. The beam transport device, typically a vacuum system containing a series of focusing devices, transports the ion beam to the wafer processing device while maintaining desired properties of the ion beam. Finally, semiconductor wafers are transferred into and out of the wafer processing device via a wafer handling system, which may include one or more robotic arms, for placing a wafer to be treated in front of the ion beam and removing treated wafers from the ion implanter.

In RF-based accelerators and DC based accelerators, ions can be repeatedly accelerated through multiple acceleration stages of an accelerator. For example, RF based accelerators can have voltage-driven acceleration gaps. Due to the time varying nature of RF acceleration fields and the multiple numbers of acceleration gaps, there are a large number of parameters that influence the final beam energy. Because the charge state distribution of an ion beam can change, substantial effort is paid to keep the charge value in the ion beam at the initially intended single value. However, greater demands for an implantation recipe (e.g., ion beam energy, mass, charge value, beam current and/or total dose level of the implantation) at a higher energy level call for providing a higher beam current without compromising the ion source unnecessarily.

Accordingly, suitable systems or methods for increasing beam current are desired.

### SUMMARY

The following presents a simplified summary in order to provide a basic understanding of one or more aspects of the disclosure. This summary is not an extensive overview of the disclosure, and is neither intended to identify key or critical elements of the disclosure, nor to delineate the scope thereof. Rather, the primary purpose of the summary is to present some concepts of the disclosure in a simplified form as a prelude to the more detailed description that is presented later.

According to various embodiments, a system and method is provided to increase beam current available at a maximum kinetic energy for a charge state without using a higher or different charge state at an ion source. For example, a high energy ion implantation system is provided, wherein an ion beam source is configured to generate an ion beam comprising a plurality of ions along a beamline. A mass analyzer, for example, configured to mass analyze the ion beam from the ion source. A first RF accelerator is provided downstream of the mass analyzer and is configured to receive ions of the ion beam from the mass analyzer. The plurality of ions, for example are at an initial energy and an initial charge state, wherein the first RF accelerator is configured to accelerate the plurality of ions to a first energy at the initial charge state. The ion beam, for example, comprises a species comprising one or more of boron, phosphorus, and arsenic.

An electron stripper, for example, is positioned downstream of the first RF accelerator and configured to receive the plurality of ions at the initial charge state and first energy and to convert the plurality of ions to a plurality of charge states at the first energy. The plurality of charge states, for example, comprise a charge state that is greater than or less than the initial charge state. For example, the electron stripper is configured to convert the plurality of ions to a net charge of +2, +3, +4, and/or +5 In another example, the electron stripper is configured to convert the plurality of ions to a net charge of +6 or higher.

In accordance with one exemplified aspect, a charge selector is further positioned downstream of the electron stripper and configured to select ions of a final charge state at the first energy. A second RF accelerator, for example, is further positioned downstream of the charge selector and configured to accelerate the plurality of ions to a sub-final energy at the final charge state. Furthermore, a final energy filter is positioned downstream of the second RF accelerator and configured to convert the plurality of ions to a final charge state at a final energy for implantation into a workpiece.

According to one example, the electron stripper comprises a gas cell configured to provide a gas to create a localized high density gas region along the beamline for stripping electrons from the plurality of ions, and is configured with a control device to adjust a flow rate of the gas into the electron stripper based on at least one of an energy, a current and a species of the ion beam. A differential pumping scheme with turbo pumps may be further utilized to maintain localization of the gas pressure.

In accordance with another exemplified aspect of the disclosure, a method of operating a high energy ion implanter is provided. The method, for example, comprises generating an ion beam comprising ions of a beam species from an ion source at an initial energy and initial charge state. The ion beam is mass analyzed and ions of the initial charge state and initial energy are provided to a first RF accelerator. The ions of the initial charge state are accelerated to a first energy via the first RF accelerator, and the accelerated ions are stripped with an electron stripper downstream of the first RF accelerator. Accordingly, the ions of the initial charge state are converted to ions of a plurality of charge states, wherein the initial charge state is different from the plurality of charge states.

In one example, ions of a final charge state at the first energy are selected downstream of the electron stripper via a charge selector, and are provided to a second RF accelerator. The ions of the final charge state are accelerated to -final energy within the second RF accelerator and are provided to an energy filter, wherein the ions of the final charge state are filtered downstream of the second RF accelerator and ions at a final charge state and final energy are provided to a workpiece.

In one exemplified aspect, the electron stripper is located downstream of the first RF accelerator in a direction of the ion beam, and upstream of charge selector. In another exemplified aspect, the charge selector is positioned downstream of the electron stripper and first RF accelerator in a direction of the ion beam, and upstream of the second RF accelerator.

The above summary is merely intended to give a brief overview of some features of some embodiments of the present disclosure, and other embodiments may comprise additional and/or different features than the ones mentioned above. In particular, this summary is not to be construed to be limiting the scope of the present application. Thus, to the accomplishment of the foregoing and related ends, the disclosure comprises the features hereinafter described and particularly pointed out in the claims. The following description and the annexed drawings set forth in detail certain illustrative embodiments of the disclosure. These embodiments are indicative, however, of a few of the various ways in which the principles of the disclosure may be employed. Other objects, advantages and novel features of the disclosure will become apparent from the following detailed description of the disclosure when considered in conjunction with the drawings.

### BRIEF DESCRIPTION OF THE DRAWINGS

FIG. 1 is a schematic of an ion implantation system having a charge selector positioned after an RF post-accelerator;

FIG. 2 is a schematic of an ion implantation system according to at least one aspect of the present disclosure;

FIG. 3 is a graph illustrating a final energy spectrum exiting an RF accelerator according to one example of the present disclosure; and

FIG. 4 is a flow chart diagram illustrating a method of increasing beam current according to yet another embodiment of the present disclosure.

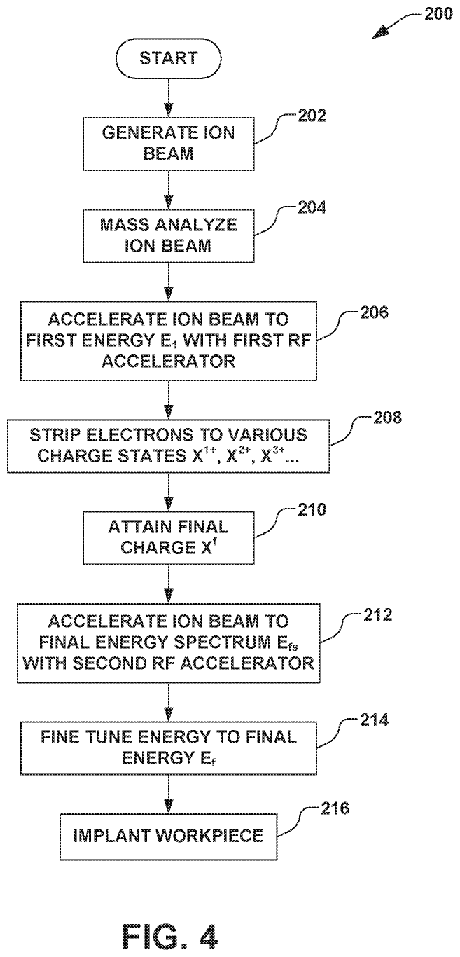

### DETAILED DESCRIPTION

The present disclosure is directed generally toward a system, apparatus, and method for method for increasing beam current available at a maximum energy for a charge state without using a higher charge state at an ion source. Accordingly, the present disclosure will now be described with reference to the drawings, wherein like reference numerals may be used to refer to like elements throughout. It is to be understood that the description of these aspects are merely illustrative and that they should not be interpreted in a limiting sense. In the following description, for purposes of explanation, numerous specific details are set forth in order to provide a thorough understanding of the present disclosure. It will be evident to one skilled in the art, however, that the present disclosure may be practiced without these specific details. Further, the scope of the invention is not intended to be limited by the embodiments or examples described hereinafter with reference to the accompanying drawings, but is intended to be only limited by the appended claims and equivalents thereof.

It is also noted that the drawings are provided to give an illustration of some aspects of embodiments of the present disclosure and therefore are to be regarded as schematic only. In particular, the elements shown in the drawings are not necessary to scale with each other, and the placement of various elements in the drawings is chosen to provide a clear understanding of the respective embodiment and is not to be construed as necessarily being a representation of the actual relative locations of the various components in implementations according to an embodiment of the disclosure. Furthermore, the features of the various embodiments and examples described herein may be combined with each other unless specifically noted otherwise.

It is also to be understood that in the following description, any direct connection or coupling between functional blocks, devices, components, circuit elements or other physical or functional units shown in the drawings or described herein could also be implemented by an indirect connection or coupling. Furthermore, it is to be appreciated that functional blocks or units shown in the drawings may be implemented as separate features or circuits in one embodiment, and may also or alternatively be fully or partially implemented in a common feature or circuit in another embodiment. For example, several functional blocks may be implemented as software running on a common processor or controller.

In a conventional ion implantation system comprising a radio frequency (RF) linear accelerator (linac), a maximum energy of ions is generally determined, to first order, by the number of the accelerating gaps and the charge state of injected ions. Such a maximum energy of the ions, for example, is substantially due to the RF voltage across a single gap being primarily limited to around 100 KV. In order to obtain higher energy per gap, the use of a higher charge state ion has been the most effective method, since the energy can be accordingly doubled, tripled, or even quadrupled. Additional resonators (e.g., a number of accelerating gaps) has been another straightforward method for increasing energy, but has not been shown to be as efficient. In practice, both methods can be used together to attain desired higher ion energies.

However, the use of higher charge state ions has its limitations. In a conventional RF linac, the charge state remains constant, whereby the desired high charge state ions are created at the ion source and injected into the RF linac. In other words, the ions emerging from the conventional RF linac are of the same charge state ions as ions injected into the RF linac. Such a constant charge state, however, the ion source produces yields of higher charge state ions that are far less than low charge state ions, such as 1⁺ ions. A crude rule of thumb is that the yield from a conventional ion source decreases by 1/10 when increasing charge to the next higher charge state. For example, according to this crude rule, a 4⁺ ion yield will be 1/1000 of 1⁺ ions, or 1 uA of 4⁺ ions for 1 mA on 1⁺ ions. Such yields are not efficient. For lighter Z ions, such as Boron, the decrease in yield is greater than 1/10 and is very hard to attain high charge state ions, whereas for heavier Z ions, such as Arsenic, the decrease in yield is less than 1/10. As such, the output beam current on a substantially high energy beam in an RF linac implanter tends to be quite small, since it depends on using high charge state ions. While increasing the number of resonators may appear to be a solution, increasing the number of resonators can lead to large increases in power consumption, an increase in tool size (e.g., electrodes increase in length, thus increasing a length of the implanter in a non-linear manner with respect to the number of resonators), and a more complex and less reliable control system.

Co-owned U.S. Pat. No. 8,035,080 to Satoh, the contents of which is incorporated by reference herein in its entirety, provides a method to produce a higher amount of high charge state ions by utilizing a charge stripping method on an RF accelerator, rather than extracting the high charge state ions from an ion source. In order to achieve a higher number of high charge state ions by charge stripping, as opposed to by extracting the high charge state ions directly from an ion source, ions are accelerated to a high energy (e.g., high velocity), typically on the order of MeVs when the ions enter a charge stripper.

For example, as high as 70% of 3 MeV Boron (of any charge states) is converted to charge state 3⁺, thus providing an efficient means to obtain 3⁺ ions, considering 3⁺ ions are usually less than 1% of 1⁺ of a Boron ion beam emerging from the ion source. In order to benefit the efficiency of high charge state ions by charge stripping, the ions are first accelerated to a high energy (e.g., via a first RF accelerator or “pre-accelerator”), typically to several MeV, and then passed through a charge stripper. The high charge state ions emerging from the charge stripper are then accelerated again (e.g., via a second RF accelerator or “post accelerator”) in order to harvest a higher energy gain in the second RF accelerator associated with the higher charge states.

It is noted that the charge stripper produces many ions of different charge states, whereby fractions vary mainly with ion energy. In the Satoh patent, all the ions of different charge states from the charge stripper are directed to the second RF accelerator. On the other hand, in a DC accelerator, or a so-called “tandem accelerator” that does not discriminate charge state on acceleration of the ions, the ion beam emerging from the post accelerator contains many ions having differing charge states, with the same fraction of ions at the exit of the charge stripper. Since energy gains through the post-accelerator are proportional to the charge state, on DC accelerators, an energy spectrum at the exit of the post accelerator contains several discrete peaks separated by the difference in energy gain by the charge states. A charge selector, being a filter achieved by either by magnetic field or electric field, is thus placed after the post accelerator to pick only ions of a predetermined energy, (e.g., a single charge state).

When the post accelerator is an RF linac, however, the RF linac acts as a velocity selector, whereby its acceleration is optimized for one charge state which arrives at the multiple acceleration gaps at a predetermined phase of RF acceleration voltage, even when an input ion beam has several different charge states, such as the ion beam emerging from the charge stripper. The output energy spectrum, for example, contains a single peak of the desired ion species. However, the emerging ion beam also contains other charge states which enter the RF linac and are gradually decelerated as they proceed through the RF linac, whereby some ions reach exit of the RF linac at much lower energies. Since such ions do not synchronize with the RF frequency, their energies constitute significantly random spectra, such as a continuous broad spectra with different charge states. A problem posed by such a broad spectra of an ion beam with various charge states is that some of the ions may possess the same rigidity as the desired beam, and may thus pass through the final charge selector together with the desired beam, which can cause energy contamination at the workpiece.

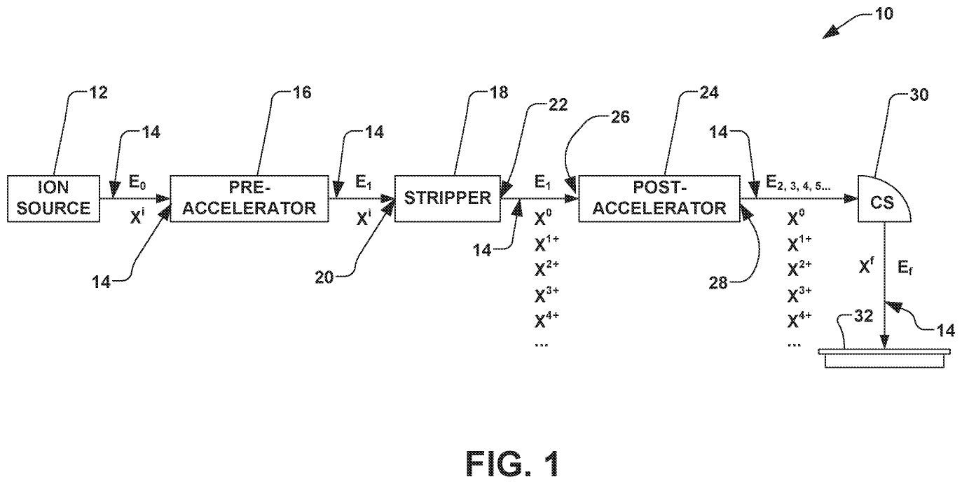

A non-limiting example of an RF ion implantation system 10 is illustrated in FIG. 1, wherein an ion source 12 produces an ion beam 14 with ions X having an initial charge state Xⁱ at an initial ion energy E₀. An RF pre-accelerator 16 (e.g., a first RF linac) accelerates ions of the ion beam 14 and increases the energy of the ion beam from the initial ion energy E₀ to a first energy E₁, while the initial charge state Xⁱ of the ions X of the ion beam is generally maintained. The ion beam 14 is then passed through an electron stripper 18 (e.g., a gas stripper), whereby the electron stripper changes the composition of the charge state of the ions X of the ion beam. For example, in an exemplified electron stripper 18, as the ion beam 14 enters a stripper entrance 20 of the electron stripper, the ions pass through a layer of gas in the electron stripper, whereby the ions can change charge states, where some of the ions increase in charge state, while others acquire electrons to decrease in charge state. Thus, upon exiting the electron stripper 18, the energy first energy E₁ of the ions X remains substantially the same, as no acceleration is generally provided to the ion beam 14 by the electron stripper; however, the electron stripper accordingly produces ions with various first, second, third, fourth, etc. charge states (e.g., X⁰, X¹⁺, X²⁺, X³⁺, X⁴⁺, etc.) at an exit 22, thereof.

The ions X of the ion beam 14 having the various charge states is then passed to an RF post-accelerator 24 (e.g., a second RF linac). For example, depending on the charge state X⁰, X¹⁺, X²⁺, X³⁺, X⁴⁺, etc. of the ions of the ion beam 14 entering the RF post-accelerator 24 at an entrance 26 thereof, such ions are accelerated from the first energy E₁ and exit the RF post-accelerator at various energies E₂, E₃, E₄, E₅, etc. Thus, at an exit 28 of the RF post-accelerator 24, various combinations of energies E₂, E₃, E₄, E₅, etc. and charge states X⁰, X¹⁺, X²⁺, X³⁺, X⁴⁺, etc. are exhibited by the ions in the ion beam 14, although primarily one charge state gets preferential acceleration due to the RF accelerator acting as a velocity filter. As such, a charge selector 30 is implemented to select a final energy E_{f} and final charge state X_{f}, such as one of X³⁺, X⁴⁺, etc. The charge selector 30, for example, may comprise a dipole magnet acting as a magnetic filter that is configured to select the desired charge of ions exiting the charge selector.

The above-described configuration of an ion implantation system generally performs well in producing the desired ions for the vast majority of the ion beam 14 (e.g., approximately 99% effectiveness), but for a small number of ions (e.g., 1% or less of the ion beam), some contamination can occur, whereby ions of undesired charges can pass through the charge selector 30. The magnetic filter of the charge selector 30, for example, is configured to select ions based on magnetic rigidity, whereby the magnetic rigidity of an ion is a function of the mass M and energy E of the ion divided by its charge q:

$$Magnetic Rigidity = \sqrt{\frac{M \times E}{q}} . \qquad ( 1 )$$

As such, if the ratio of square root of energy E and charge q happens to be the same for variously-charged ions of differing energies, the charge selector 30 is no longer adequate to provide the desired selection of ions of only a specific energy, and passes undesired ions in the ion beam 14 through the charge selector. For example, for desired ions of charge state 4+ having an energy of E, if there are ions of the ion beam with charge state 2+ with the energy of E/4, these ions can pass through the filter, where the final ion beam will constitute ions of two different energies, the lower one of which is undesired and often called Energy Contamination, or EC. While the undesired ions may be approximately 1% or less of the entirety of the ion beam 14 exiting the charge selector 30, such undesired ions (e.g., lower energy or lower charge state than desired) may become problematic when implanted into the workpiece 32.

For example, problems associated with the energy and charge state of ions being lower than desired, even in small amounts (e.g., 1% of lower than desired energy and/or charge state ions mixed with 99% of desired energy and charge state ions), can lead to various deleterious issues in resulting devices on the workpiece 32, especially when higher charge states are desired. In the system 10 described above, the RF post accelerator 24 also acts to a degree, as an energy filter. However, if the RF post-accelerator 24 is not adequately efficient, and if enough ions are accelerated to various energies and reach the charge selector 30, the charge selector may not be able to provide adequate filtering.

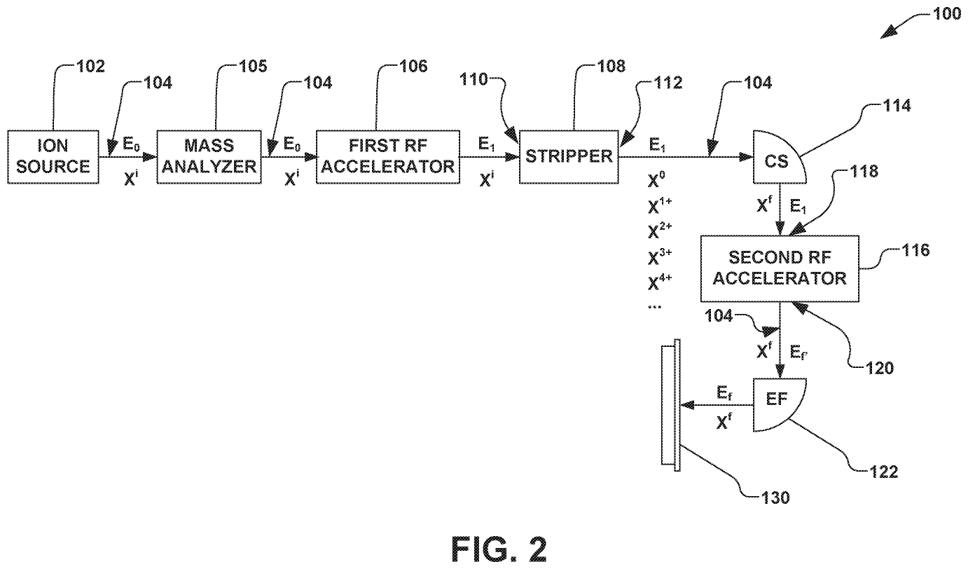

The present disclosure provides a solution to the above problem in RF-accelerated ion implantation systems. In accordance with one aspect of the present disclosure, as illustrated in FIG. 2, an RF ion implantation system 100 is provided, whereby an ion source 102 produces an ion beam 104 with ions of species X (e.g., boron or other species) having an initial charge state Xⁱ at an initial ion energy E₀. The ion beam 104 is mass analyzed by a mass analyzer 105, and a first RF accelerator 106 (e.g., a first RF linac) accelerates ions of the ion beam 104 and increases the energy of the ion beam from the initial ion energy E₀ to a first energy E₁, while the initial charge state Xⁱ of the ions of the ion beam is generally maintained. The ion beam 104 is then passed through an electron stripper 108 (e.g., a charge stripper), whereby the electron stripper changes the composition of the initial charge state Xⁱ of the ions X of the ion beam. The electron stripper 108, for example, comprises a gas cell (not shown) configured to supply a gas for stripping electrons from the plurality of ions and a control device (not shown) configured to adjust a flow rate of the gas into the electron stripper based on at least one of an energy, a current and a species of the ion beam 104. As the ion beam 104 enters a stripper entrance 110 of the electron stripper 108, for example, the particles or ions X of the ion beam pass through a thin layer of gas introduced within the electron stripper, whereby electrons can be stripped or gained by charge exchange reactions, and the distribution of the final charge states depends on the particle velocity from the ions. Some of the ions increase in charge state (e.g., X¹⁺ to X²⁺) while others acquire electrons to decrease in charge state (X²⁺ to X¹⁺). For example, for an ion beam 104 comprising boron ions, charge exchange reactions between the ion beam and the layer of atoms of the electron stripper 108 can change the charge state of various ions from an initial value provided in a process recipe to another charge state (e.g., for boron, a change in charge state from B¹⁺ to B²⁺, or B²⁺ to B¹⁺, etc.), while maintaining the same energy.

Thus, upon exiting the electron stripper 108 at a stripper exit 112, the first energy E₁ of the ions remains substantially the same, as no acceleration is generally provided to the ion beam 104 by the electron stripper. However, the electron stripper 108 accordingly produces ions with a plurality of charge states (e.g., X⁰, X¹⁺, X²⁺, X³⁺, X⁴⁺, etc.) at the stripper exit 112.

In accordance with the present disclosure, the ions of the ion beam 104, having the plurality of charge states (e.g., X⁰, X¹⁺, X²⁺, X³⁺, X⁴⁺, etc.) is then passed to a charge selector 114 downstream of the energy stripper 108, whereby a final charge state X^{f} of the ions of the ion beam 104 is selected prior to the ions entering a second RF accelerator 116 (e.g., a second RF linac) at an entrance 118 of the second RF accelerator. The charge selector 114, for example, comprises two 45-degree magnets with a quadrupole singlet lens therebetween, to form an achromatic beam bending system. As such, the second RF accelerator 116 is thus met with ions of only the single, final charge state X^{f} at the first energy E₁ from the charge selector 114 prior to the ions entering the second RF accelerator, whereby the ions emerge from the second RF accelerator at an exit 120 of the second RF accelerator to the final energy.

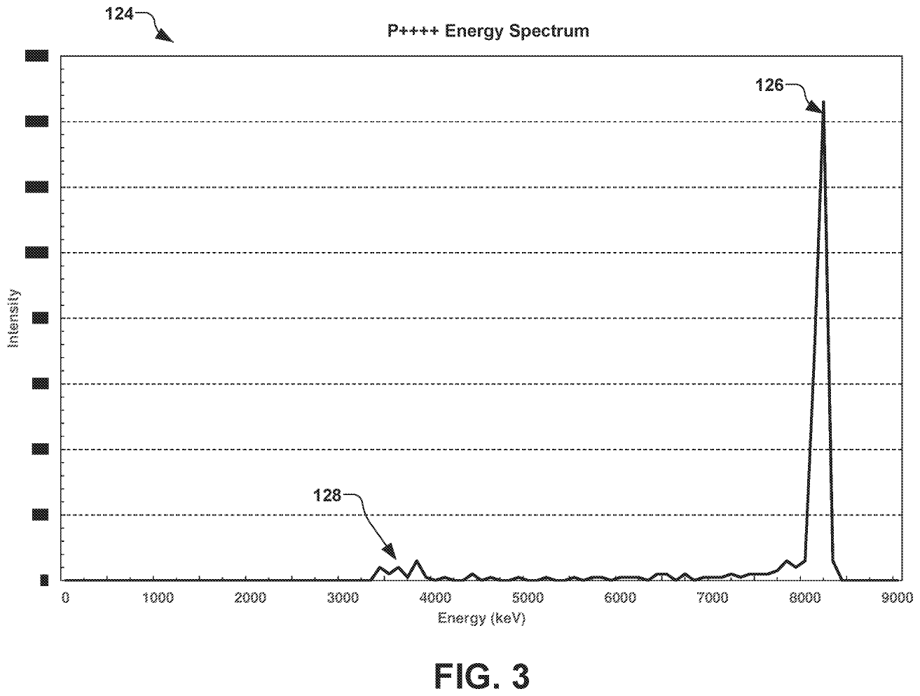

Accordingly, a final energy filter 122 (e.g., a dipole magnet) is further employed downstream of the second RF accelerator 116 to purify a final energy spectrum E_{fS} by removing a small amount of ions with off-peak energies, which may happen to miss the RF acceleration timing at various stages of the accelerations in the second RF accelerator. The final energy filter 122, for example, is provided to produce ions of the final charge state X^{f} at a final energy E_{f}, since the ions of the final energy spectrum E_{fS} emerging from the second RF accelerator are primarily of a single species of charge state, but may still contain off-peak energies. FIG. 3 illustrates an example final energy spectrum 124 of RF acceleration prior to entering the final energy filter 122 of FIG. 2. As shown in FIG. 3, a peak energy 126 associated with the final energy E_{f} is evident in the final energy spectrum 124. However, off-peak energies 128 are also present in the final energy spectrum 124 entering the final energy filter 122 of FIG. 2, whereby the purification provided by final energy filter removes such off-peak energies from the ion beam, thus advantageously purifying the ion beam 104 to the final energy E_{f}.

Accordingly, the charge selector 114 is advantageously positioned upstream of the second RF accelerator 116, whereby the first energy E₁ that emerges from the first RF accelerator 106 and electron stripper 108 is increased by the second RF accelerator 116 after the final desired charge state X^{f} is selected, thus increasing an efficiency of the ion implantation system 100 over conventional systems.

For example, in the ion implantation system 10 of FIG. 1, multiple energies E₂, E₃, E₄, E₅, etc. of the ion beam 14 emerge from the RF post-accelerator 24 and are fed into the charge selector 30. However, in accordance with the present disclosure, ions having the first energy E₁ enter both the charge selector 114 and the second RF accelerator of FIG. 2, such that the single first energy E₁ is accelerated to the primarily singular final energy spectrum E_{fS}, emerging from the second RF accelerator with the final charge state X^{f}. Then, the final energy filter 122 thus provides a purification to the final energy spectrum E_{fS} to provide the final energy E_{f} and final charge state X^{f} to a workpiece 130. For example, any ions that may have a lower energy state or charge value are filtered by the energy filter 122 prior to being implanted into the workpiece 130, thus eliminating deleterious energy contamination seen in previous systems.

The present disclosure advantageously implements the first RF accelerator 106 and second RF accelerator 116 having the electron stripper 108 and charge selector 114 disposed therebetween, as opposed to a DC accelerators (so-called “tandem accelerators”), which require a high voltage in the middle of the beamline (e.g., approximately one megavolt or more). The present disclosure is thus advantageous for lighter ions such as boron, phosphorous, arsenic, etc. Since the first RF accelerator 106 and second RF accelerator 116 are substantially separated by the electron stripper 108 and charge selector 114, a greater amount of beam current of the ion beam.

Thus, in accordance with the present disclosure, the ion beam 104 enters the second RF accelerator 116 with only one charge state, the final charge state X^{f}, which generally eliminates the creation of spurious ions of a broad energy spectrum heretofore seen as a source of energy contamination. Thus, the present disclosure provides a high energy ion implantation system having multiple RF linear acceleration components in an RF Linac beamline. The present disclosure, for example, has advantages where space constraints in a fabrication facility lead to separated RF linear acceleration components.

Referring now to FIG. 3, a method 200 for high energy ion implantation is provided. It should also be noted that while exemplary method(s) are illustrated and described herein as a series of acts or events, it will be appreciated that the present disclosure is not limited by the illustrated ordering of such acts or events, as some steps may occur in different orders and/or concurrently with other steps apart from that shown and described herein, in accordance with the disclosure. In addition, not all illustrated steps may be required to implement a methodology in accordance with the present disclosure. Moreover, it will be appreciated that the methods may be implemented in association with systems illustrated and described herein as well as in association with other systems not illustrated.

As illustrated in FIG. 3, the method 200 begins at act 202, wherein an ion beam is generated in an ion source having ion(s) at an initial energy E₀ and an initial charge state(s) Xⁱ. The ion beam, for example, is directed into a mass analyzer, wherein in act 204, the ion beam is mass analyzed. For example, a magnetic field strength for the mass analyzer can be selected according to a charge-to-mass ratio. The ion beam, after being mass analyzed in act 204, is passed into a first RF accelerator in act 206, whereby selected ion(s) of the initial charge state(s) Xⁱ are accelerated from the initial energy E₀ to a first energy E₁, which yields a higher stripping efficiency to a higher charge state than is otherwise available at the ion source.

The accelerated ion(s) of the initial charge state(s) Xⁱ enter an electron stripper in act 208, whereby accelerated ion(s) are stripped and converted to ion(s) of a plurality of charge states (e.g., X⁰, X¹⁺, X²⁺, X³⁺, X⁴⁺, etc.) at the first energy E₁. In act 210, a final charge state X^{f} is selected from the ions of various charge states by a charge selector. In act 212, the ions at the final charge state X^{f} and first energy E₁ are then passed to a second RF accelerator, whereby the ions are accelerated to a final energy spectrum E_{fS} at the final charge state X^{f}. In act 214, a final energy filter provides a purification on the final energy spectrum E_{fS} of the ion(s) at the final energy E_{f} to yield a final energy E_{f} and final charge state X^{f} for implantation into a workpiece in act 216.

Although the disclosure has been shown and described with respect to a certain applications and implementations, it will be appreciated that equivalent alterations and modifications will occur to others skilled in the art upon the reading and understanding of this specification and the annexed drawings. In particular regard to the various functions performed by the above described components (assemblies, devices, circuits, systems, etc.), the terms (including a reference to a “means”) used to describe such components are intended to correspond, unless otherwise indicated, to any component which performs the specified function of the described component (i.e., that is functionally equivalent), even though not structurally equivalent to the disclosed structure, which performs the function in the herein illustrated exemplary implementations of the disclosure.

In addition, while a particular feature of the disclosure may have been disclosed with respect to only one of several implementations, such feature may be combined with one or more other features of the other implementations as may be desired and advantageous for any given or particular application. Furthermore, to the extent that the terms “includes”, “including”, “has”, “having”, and variants thereof are used in either the detailed description or the claims, these terms are intended to be inclusive in a manner similar to the term “comprising”.

1. A high energy ion implantation system, comprising:
an ion beam source configured to generate an ion beam comprising a plurality of ions along a beamline;
a mass analyzer configured to mass analyze the ion beam;
a first RF accelerator configured to receive the ion beam from the mass analyzer, wherein the plurality of ions are at an initial energy and an initial charge state, wherein the first RF accelerator is further configured to accelerate the plurality of ions to a first energy at the initial charge state;
an electron stripper positioned downstream of the first RF accelerator and configured to receive the plurality of ions at the initial charge state and first energy and to convert the plurality of ions to a plurality of charge states at the first energy;
a charge selector positioned downstream of the electron stripper and configured to select a final charge state at the first energy from the plurality of charge states of the plurality of ions;
a second RF accelerator positioned downstream of the charge selector and configured to accelerate the plurality of ions to a final energy spectrum at the final charge state; and
a final energy filter positioned downstream of the second RF accelerator and configured to purify the plurality of ions to a final energy at the final charge state for implantation into a workpiece.

2. The system of claim 1, further comprising an end station positioned downstream of the final energy filter and configured to support the workpiece.

3. The system of claim 1, wherein the electron stripper comprises a gas cell configured to provide a gas to create a localized high density gas region along the beamline for stripping electrons from the plurality of ions and a control device configured to adjust a flow rate of the gas into the electron stripper based on at least one of an energy, a current and a species of the ion beam.

4. The system of claim 1, wherein the variety of charge states comprise a charge state that is greater than or less than the initial charge state.

5. The system of claim 1, the ion beam comprises a species comprising one or more of boron, phosphorus, and arsenic.

6. The system of claim 1, wherein the electron stripper is configured to convert the plurality of ions to a net charge of one or more of +2, +3, +4, and +5.

7. The system of claim 1, wherein the electron stripper is configured to convert the plurality of ions to a net charge of +6 or higher.

8. The system of claim 1, wherein the electron stripper comprises a gas stripper.

9. An ion implantation system, comprising:
an ion beam source configured to generate an ion beam comprising a plurality of ions along a beamline;
a mass analyzer configured to mass analyze the ion beam;
a first RF accelerator configured to receive the ion beam from the mass analyzer, wherein the plurality of ions are at an initial energy and an initial charge state, wherein the first RF accelerator is further configured to accelerate the plurality of ions to a first energy at the initial charge state;
an electron stripper positioned downstream of the first RF accelerator and configured to receive the plurality of ions at the initial charge state and first energy and to convert the plurality of ions to a plurality of charge states at the first energy;
a charge selector positioned downstream of the electron stripper and configured to convert the plurality of ions to a final charge state at the first energy;
a second RF accelerator positioned downstream of the charge selector and configured to accelerate the plurality of ions to a final energy spectrum at the final charge state;
a final energy filter positioned downstream of the second RF accelerator and configured to convert the plurality of ions to a final charge state at a final energy for implantation into a workpiece.

10. The ion implantation system of claim 9, further comprising an end station positioned downstream of the final energy filter and configured to support the workpiece.

11. The ion implantation system of claim 9, wherein the electron stripper comprises a gas cell configured to provide a gas to create a localized high density gas region along the beamline for stripping electrons from the plurality of ions and a control device configured to adjust a flow rate of the gas into the electron stripper based on at least one of an energy, a current and a species of the ion beam.

12. The ion implantation system of claim 9, wherein the variety of charge states comprise a charge state that is greater than or less than the initial charge state.

13. The ion implantation system of claim 9, the ion beam comprises a species comprising one or more of boron, phosphorus, and arsenic.

14. The ion implantation system of claim 9, wherein the electron stripper is configured to convert the plurality of ions to a net charge of greater than +1.

15. The ion implantation system of claim 8, wherein the electron stripper comprises a gas stripper.

16. A method of operating a high energy ion implanter comprising:
generating an ion beam comprising ions of a beam species from an ion source at an initial energy and initial charge state;
mass analyzing the ion beam;
providing ions of the initial charge state and initial energy to a first RF accelerator;
accelerating the ions of the initial charge state to a first energy with first RF accelerator;
stripping the accelerated ions with an electron stripper downstream of the first RF accelerator, thereby converting the ions of the initial charge state to ions of a plurality of charge states, wherein the initial charge state is different from the plurality of charge states;
selecting ions of a final charge state at the first energy downstream of the electron stripper via a charge selector;
providing the ions of the final charge state at the first energy to a second RF accelerator;
accelerating the ions of the final charge state to a final energy spectrum within the second RF accelerator; and
filtering the ions of the final charge state to a final energy downstream of the second RF accelerator to provide the ions at the final charge state and final energy to a workpiece.

17. The method of claim 16, comprising supplying a gas within the electron stripper for stripping an electron from respective ions of the first charge state to convert the ions of the first charge state to ions of the second charge state, and adjusting a flow rate of the gas into the electron stripper based on at least one of energy, current and/or species of the ion beam.

18. The method of claim 16, wherein the plurality of charge states comprise a more positive charge state than the initial charge state.

19. The method of claim 16, wherein the electron stripper is located downstream of the first RF accelerator in a direction of the ion beam, and upstream of charge selector.

20. The method of claim 16, wherein the charge selector is downstream of the electron stripper and first RF accelerator in a direction of the ion beam, and upstream of the second RF accelerator.
